(19) United States
(12) Patent Application Publication
(10) Pub. No.: US 2013/0161674 A1
(43) Pub. Date: Jun. 27, 2013

(54) SEMICONDUCTOR LIGHT EMITTING ELEMENT AND METHOD FOR MANUFACTURING SAME

(71) Applicant: Shuji ITONAGA, Kanagawa-ken (JP)

(72) Inventor: Shuji ITONAGA, Kanagawa-ken (JP)

(73) Assignee: Kabushiki Kaisha Toshiba, Tokyo (JP)

(21) Appl. No.: 13/601,616

(22) Filed: Aug. 31, 2012

(30) Foreign Application Priority Data
Dec. 27, 2011 (JP) 2011-286449

(51) Int. Cl. H01L 33/60

(52) U.S. Cl. 257/98; 438/29; 257/E33.06

(57) ABSTRACT

A semiconductor light emitting element includes a stacked body, a metal reflection layer and a metal pad portion. The stacked body is made of InₓGa_{y}Al_{1-x-y}N (0≦x≦1, 0≦y≦1, x+y≦1), has a first surface and a second surface on an opposite side of the first surface and includes a light emitting layer. The metal reflection layer is provided on the first surface of the stacked body, includes silver or a silver alloy and has a mesh-like structure. The metal pad portion is provided so as to cover the first surface of the stacked body exposed at an opening provided in the mesh-like structure and a surface of the metal reflection layer. Light emitted from the light emitting layer is emitted from the second surface side of the stacked body.

### CROSS-REFERENCE TO RELATED APPLICATIONS

This application is based upon and claims the benefit of priority from the prior Japanese Patent Application No. 2011-286449, filed on Dec. 27, 2011; the entire contents of which are incorporated herein by reference.

### FIELD

Embodiments described herein relate generally to a semiconductor light emitting element and a method for manufacturing same.

### BACKGROUND

Semiconductor light emitting elements made of a nitride-based semiconductor are being widely used for illuminating equipment, display devices, traffic signals, etc.

In the semiconductor light emitting element, if a reflection metal layer is provided on a semiconductor layer, the light extraction efficiency can be increased by reflecting the light emitted from a light emitting layer.

However, materials such as gold, platinum, and titanium have a low light reflectance at short wavelength range of violet to blue light. For example, for light of a wavelength of 400 nm, the light reflectance of gold is approximately 39% and the reflectance of platinum is approximately 53%.

In contrast, for example, the light reflectance of silver is as high as approximately 94% at a wavelength of 400 nm. However, the contact resistance between the silver and the nitride-based stacked body may become high in a heat treatment process for enhancing the adhesion between silver and a nitride-based semiconductor, and the injection current may reduce. Consequently, the light output may not be sufficiently increased even though the light reflectance is increased.

### BRIEF DESCRIPTION OF THE DRAWINGS

FIG. 1A is a schematic plan view of a semiconductor light emitting element according to a first embodiment, and FIG. 1B is a schematic cross-sectional view taken along line A-A;

FIG. 2A is a schematic plan view of a metal reflection layer including circular island-like bodies, and FIG. 2B is a schematic cross-sectional view taken along line B-B;

FIGS. 3A to 3C are schematic views describing a method for manufacturing a semiconductor light emitting element of the first embodiment;

FIGS. 4A and 4B are schematic views describing the method for manufacturing a semiconductor light emitting element according to the first embodiment;

FIG. 5A is a schematic plan view of a light emitting device, and FIG. 5B is a schematic cross-sectional view taken along line C-C;

FIG. 6A is a schematic plan view of a semiconductor light emitting element according to a comparative example, and FIG. 6B is a schematic cross-sectional view taken along line D-D;

FIG. 7A is an optical microscope photograph showing a near field pattern of a semiconductor light emitting element according to the comparative example, and FIG. 7B is an optical microscope photograph showing a near field pattern of a semiconductor light emitting element according to the first embodiment;

FIG. 8A is a graph showing the distribution of silver and gallium in the central portion of the metal reflection layer, and FIG. 8B is a graph showing the distribution of silver and gallium in the peripheral portion of the metal reflection layer;

FIG. 9A is a schematic plan view of a semiconductor light emitting element according to a second embodiment, FIG. 9B is a schematic cross-sectional view taken along line E-E, and FIG. 9C is a schematic bottom view showing a light emitting region on the substrate side;

FIG. 10A is a schematic plan view of a metal reflection layer including a mesh-like structure having circular openings, and FIG. 10B is a schematic cross-sectional view taken along line F-F; and

FIG. 11 is a schematic cross-sectional view of a semiconductor light emitting element according to a third embodiment.

### DETAILED DESCRIPTION

In general, according to one embodiment, a semiconductor light emitting element includes a stacked body, a metal reflection layer and a metal pad portion. The stacked body is made of InₓGa_{y}Al_{1-x-y}N (0≦x≦1, 0≦y≦1, x+y≦1), has a first surface and a second surface on an opposite side of the first surface and includes a light emitting layer. The metal reflection layer is provided on the first surface of the stacked body, includes silver or a silver alloy and has a mesh-like structure. The metal pad portion is provided so as to cover the first surface of the stacked body exposed at an opening provided in the mesh-like structure and a surface of the metal reflection layer. Light emitted from the light emitting layer is emitted from the second surface side of the stacked body.

Various embodiments will be described hereinafter with reference to the accompanying drawings.

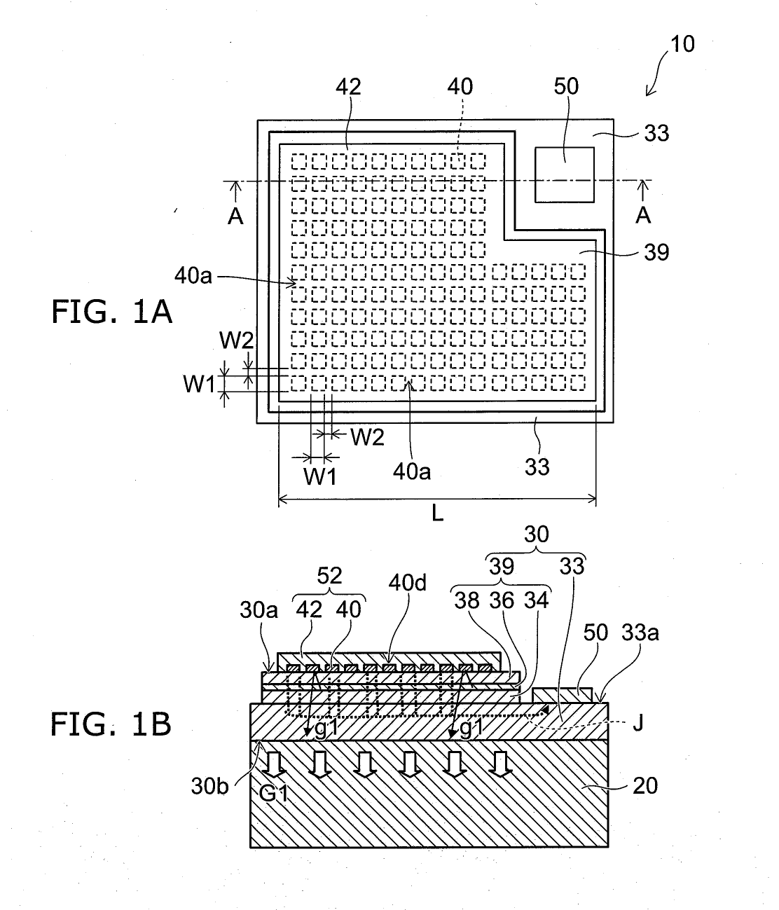

FIG. 1A is a schematic plan view of a semiconductor light emitting element according to a first embodiment, and FIG. 1B is a schematic cross-sectional view taken along line A-A.

A semiconductor light emitting element 10 includes a substrate 20, a stacked body 30 provided on the substrate 20 and made of InGaAlN-based materials, a first electrode 50, and a second electrode 52. The stacked body 30 has a first surface 30a and a second surface 30b on the opposite side of the first surface 30a.

The substrate 20 is made of a transparent material such as, for example, sapphire, and is provided on the second surface 30b side of the stacked body 30.

The stacked body 30 includes a first layer 33, a second layer 34, a light emitting layer. 36, and a third layer 38 in this order on the substrate 20. The first layer 33 and the second layer 34 have a first conductivity type. The third layer 38 has a second conductivity type. The second layer 34, the light emitting layer 36, and the third layer 38 constitute a mesa portion 39 smaller in size than the substrate 20. In the first embodiment, it is assumed that the first conductivity type is the n type and the second conductivity type is the p type. However, the invention is not limited thereto but the opposite conductivity types are possible.

In the specification, the layers constituting the stacked body 30 are made of an InGaAlN-based material expressed by the composition formula of InₓGa_{y}Al_{1-x-y}N (0≦x≦1, 0≦y≦1, x+y≦1), and may contain an element serving as an acceptor or a donor. Due to such a composition, the light emitting layer 36, for example, can emit light having wavelength range of ultraviolet to green, including blue.

The second electrode 52 is provided on the first surface 30a of the stacked body 30. The second electrode 52 includes a metal reflection layer 40 and a metal pad portion 42. As shown in FIG. 1A, the metal reflection layer 40 has an island-like structure, and is made of silver (Ag), a silver alloy, or the like. The metal pad portion 42 is provided so as to cover the first surface 30a exposed at an opening 40a between island-like bodies in the island-like structure and the surface 40d of the metal reflection layer 40 of the island-like structure.

The first electrode 50 is provided on the surface 33a of the n-type first layer 33 adjacent to the mesa portion 39. The second electrode 52 is provided on the first surface 30a (p type) of the stacked body 30. As shown in FIG. 1B, carriers injected from the second electrode 52 are high in density in the peripheral portion of the metal reflection layer 40. That is, the current density is high near the peripheral portion of the metal reflection layer 40. In the first embodiment, carries are uniformly injected from each of the metal reflection layers 40 divided into a plurality of island-like bodies. Therefore, it is easy to equalize the intensity of the current passing through each island-like body. Consequently, the light intensity distribution can be made uniform in the plane of the light emitting layer 36. A current J expressed by the dotted line flows between the first electrode 50 and the second electrode 52.

Light g1 traveling from the light emitting layer 36 toward the metal reflection layer 40 is reflected by the metal reflection layer 40, passes through the light emitting layer 36, and then is emitted from the substrate 20 (G1). Therefore, the light output can be increased. Furthermore, since also the metal pad portion 42 reflects light in response to the light reflectance of the metal material thereof, the light output can be further increased.

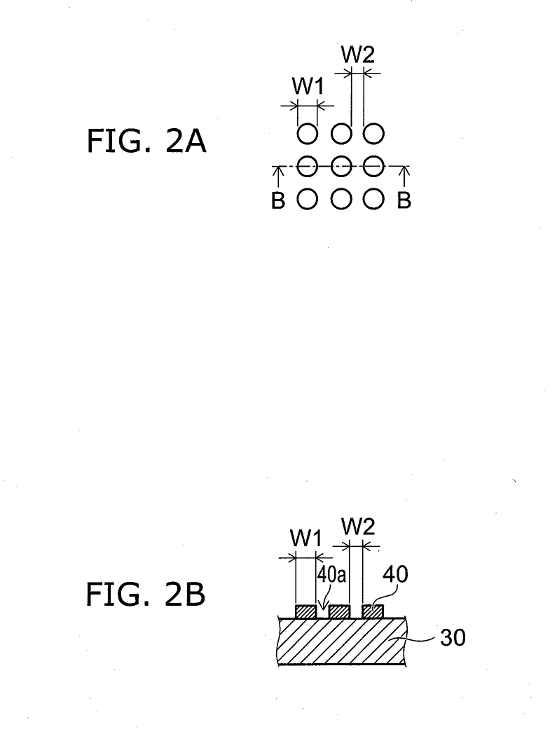

FIG. 2A is a schematic plan view of a metal reflection layer including circular island-like bodies, and FIG. 2B is a schematic cross-sectional view taken along line B-B.

The shape of the island-like body may be a rectangle, circle, ellipse, polygon, stripe, or the like. The width W1 of the island-like body is defined as the largest width of the widths of the island-like body as viewed in the plane of the metal reflection layer. The width W2 of the opening 40a is defined as the shortest distance between two island-like bodies. Although there may be a difference in size between island-like bodies, the plurality of island-like bodies are preferably made the same shape and arranged regularly because the reflection metal layer 40 can be more uniformly operated. Also when there is a difference in size between island-like bodies, the minimum value of the widths W1 of the regions of the island-like bodies is preferably set larger than the maximum value of the width W2 of the opening 40a.

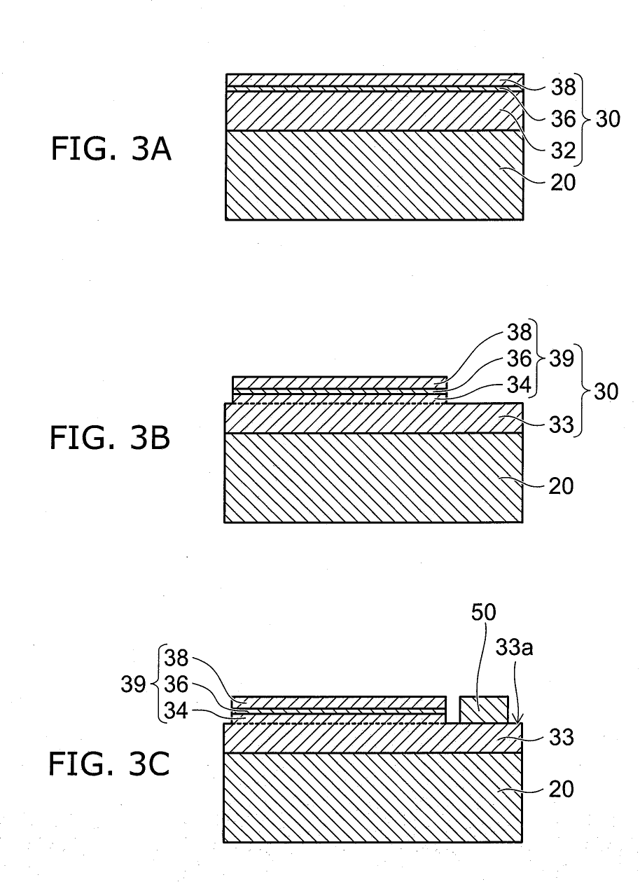

FIGS. 3A to 3C are schematic views describing a method for manufacturing a semiconductor light emitting element of the first embodiment. FIG. 3A is a schematic cross-sectional view after epitaxial growth, FIG. 3B is a schematic cross-sectional view after the formation of the mesa unit, and FIG. 3C is a schematic cross-sectional view after the formation of the first electrode.

In FIG. 3A, on the substrate 20 made of sapphire or the like and having transparency, the stacked body 30 including a first conductivity type layer 32 with the n type, the light emitting layer 36, and the third layer 38 with the p type in this order is epitaxially grown using, for example, the MOCVD (metal organic chemical vapor deposition) method, the MBE (molecular beam epitaxy) method, etc.

Subsequently, the upper portion of the stacked body 30 is etching-processed into the mesa portion 39 using the photolithography method, the RIE (reactive ion etching) method, etc. The mesa portion 39 includes the second layer 34 that is an upper portion of the first conductivity type layer 32, the light emitting layer 36, and the third layer 38 that is the p type. The second layer 34 may include, for example, a current spreading layer, a cladding layer, a light guide layer, etc.

When the light emitting layer 36 is configured to have an MQW (multi-quantum well) structure, it is easy to improve wavelength controllability and increase the light emission efficiency. The well layer included in the MQW structure may be non-doped or have electrical conductivity.

The third layer 38 may include, for example, a light guide layer, a cladding layer, a current spreading layer, a contact layer (GaN), etc.

An upper outer edge portion of the first conductivity type layer 32 is etched. An upper inner portion of the first conductivity type layer 32 is left and forms the second layer 34 of the mesa portion 39. A lower portion of the first conductivity type layer 32 forms the first layer 33. When the surface of the first layer 33 is configured to include a contact layer, the surface can serve as an ohmic contact to the first electrode 50.

Subsequently, the first electrode 50 is formed on the surface 33a of the first layer 33 using the lift-off method etc. The first electrode 50 may be, for example, a multiple-layer metal film such as Ti/Al/Ta/Ti/Pt.

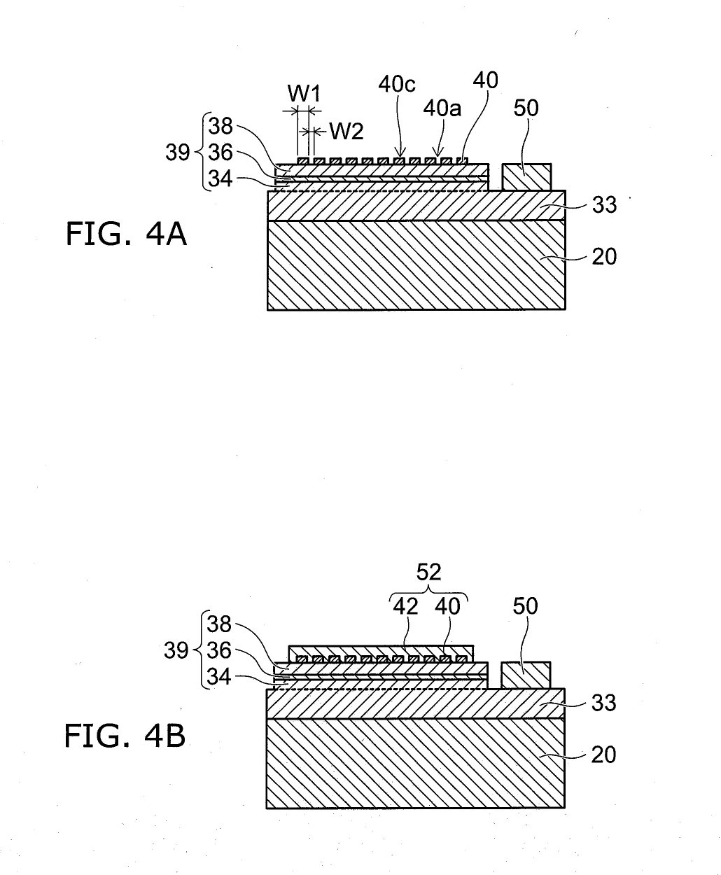

FIGS. 4A and 4B are schematic views describing the method for manufacturing a semiconductor light emitting element according to the first embodiment. FIG. 4A is a schematic cross-sectional view after the metal reflection layer is formed, and FIG. 4B is a schematic cross-sectional view after the metal pad portion is formed.

The structure of FIG. 4A is obtained by forming the metal reflection layer 40 having an island-like structure like FIG. 1A using the lift-off method etc. Further, for example, heat treatment is performed at a temperature of 300 to 500° C. in a mixed atmosphere of nitrogen and oxygen. By performing the heat treatment, the adhesion between silver and the stacked body 30 can be enhanced. The cross-sectional structure of the metal reflection layer 40 may be, for example, Ag (200 nm)/Ni (50 nm) or the like. When Ni or the like is provided on Ag, for example, oxidation and sulfuration of Ag can be suppressed. The first surface 30a of the stacked body 30 is exposed at the opening 40a.

Subsequently, as shown in FIG. 4B, the metal pad portion 42 is formed using the lift-off method etc. so as to cover the first surface 30a of the stacked body 30 exposed at the opening 40a and the surface 40c of the metal reflection layer 40. The cross-sectional structure of the metal pad portion 42 is, for example, Ti (20 nm)/Pt (50 nm)/Au (700 nm) or the like. After that, scribing is performed; thus, the semiconductor light emitting element of FIGS. 1A and 1B is completed.

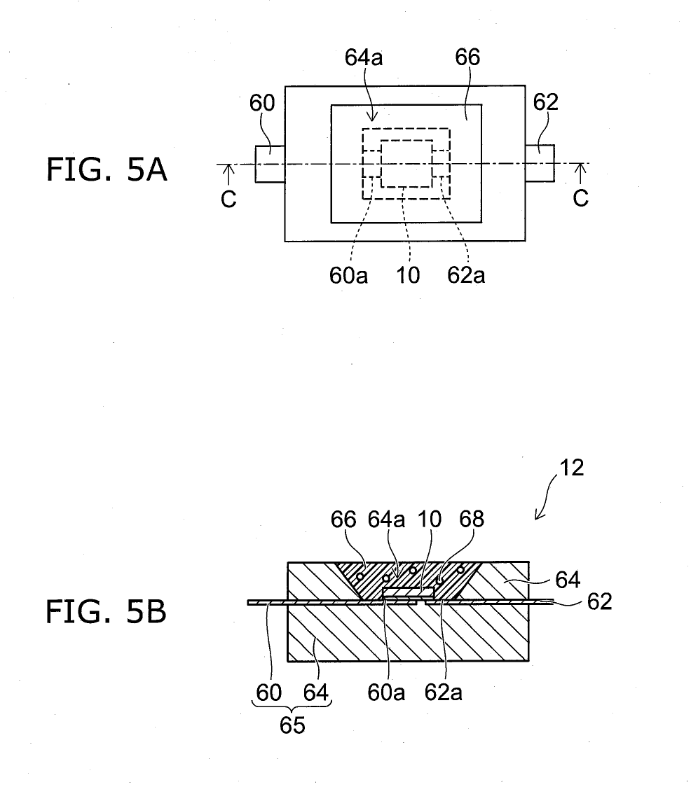

FIG. 5A is a schematic plan view of a light emitting device, and FIG. 5B is a schematic cross-sectional view taken along line C-C.

The semiconductor light emitting element 10 of the first embodiment is provided in a recess 64a of a molded body 64 included in a mounting member 65. The mounting member 65 includes a first lead 60, a second lead 62, and the molded body 64 made of a thermoplastic resin or the like and integrated with the first lead 60 and the second lead 62. The first electrode 50 of the semiconductor light emitting element 10 and the first lead 60 are bonded by a solder material, a metal bump, or the like. The second electrode 52 of the semiconductor light emitting element 10 and the second lead 62 are bonded by a solder material, a bump, or the like. Thus, light can be emitted toward the upper side of the mounting member 65. If phosphor particles 68 made of a yellow phosphor substance or the like are dispersed in a sealing resin layer 66 provided in the recess 64a, mixed light such as white light can be emitted.

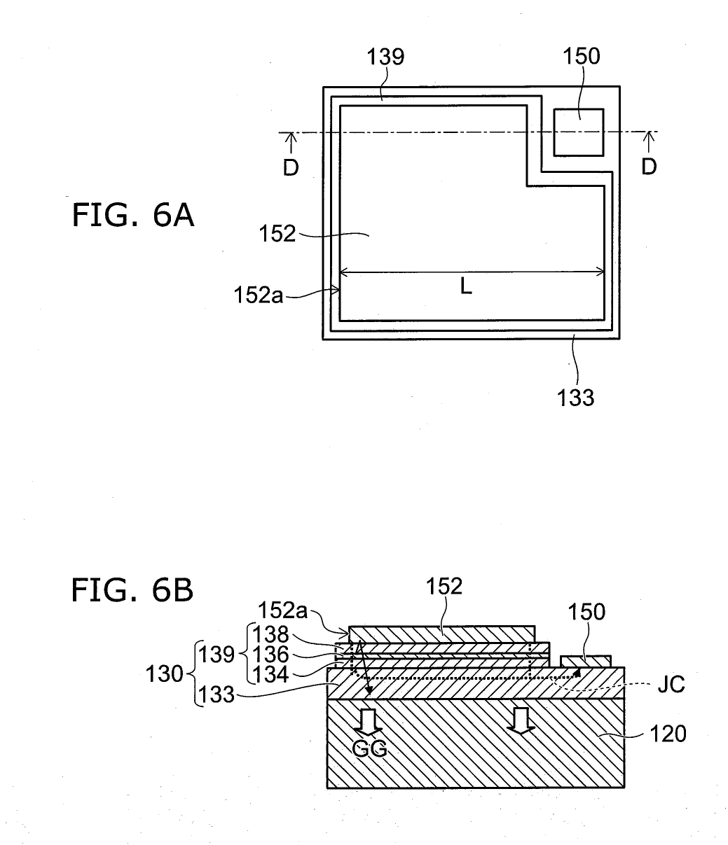

FIG. 6A is a schematic plan view of a semiconductor light emitting element according to a comparative example, and FIG. 6B is a schematic cross-sectional view taken along line D-D.

The semiconductor light emitting element according to the comparative example includes a substrate 120, a stacked body 130 provided on the substrate 120 and made of InGaAlN-based materials, a first electrode 150, and a second electrode 152. The stacked body 130 includes a first layer 133, a second layer 134, a light emitting layer 136, and a third layer 138 in this order. A mesa portion 139 includes the second layer 134, the light emitting layer 136, and the third layer 138.

The second electrode 152 has no opening, and contains silver or a silver alloy. In this case, the density of the current JC injected from the second electrode 152 into the mesa portion 139 is high in the peripheral portion of the second electrode 152 but low in the central portion, and is difficult to equalize. Consequently, emitted light GG travels from the peripheral portion of the second electrode 152 toward the substrate 120.

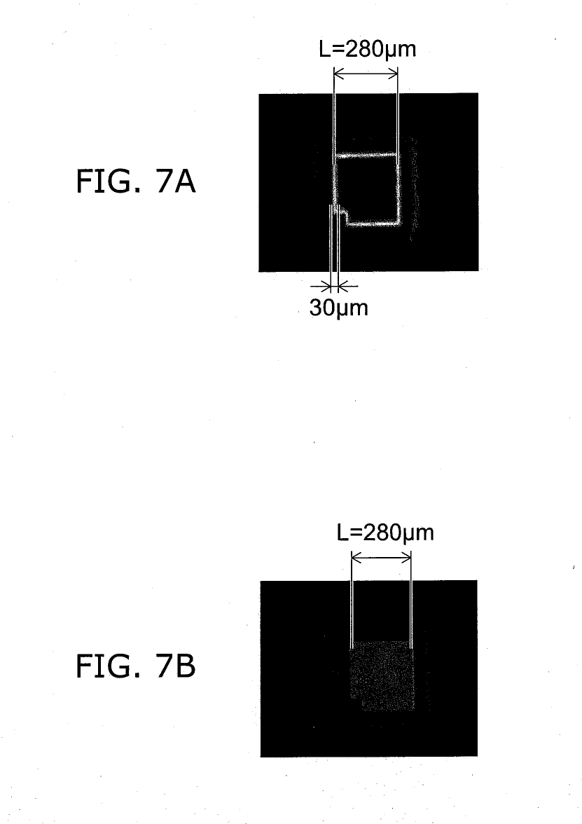

FIG. 7A is an optical microscope photograph showing a near field pattern of a semiconductor light emitting element according to the comparative example, and FIG. 7B is an optical microscope photograph showing a near field pattern of a semiconductor light emitting element according to the first embodiment.

In FIG. 7A, the thickness of the metal reflection layer 152 is set to Ag (200 nm)/Ni (50 nm). The length L of a side parallel to line D-D is set to 280 μm, and the operating current is set to 20 mA.

The inventors have found that the maximum value of the light emission intensity of the semiconductor light emitting element of the comparative example exists near the outer edge 152a of the metal reflection layer 152, and the position where the light emission intensity decreases to half the maximum value is approximately 15 μm inward and approximately 15 μm outward from the outer edge 152a. As a result, the light emission intensity in the central region of the metal reflection layer 152 was lower than half the maximum light emission intensity in the peripheral portion.

In contrast, in the semiconductor light emitting element of the first embodiment shown in FIGS. 1A and 1B, the length L of a side parallel to line A-A is set to 280 μm. The light intensity distribution of the first embodiment in which the width W1 of the plurality of rectangular island-like bodies included in the metal reflection layer 40 was set to 30 μm and the width W2 of the opening 40a was set to 3 μm was able to be made uniform in the plane of the light emitting layer 36 as shown in FIG. 7B. Furthermore, when the same voltage was applied in the forward direction, the current flowing through the semiconductor light emitting element of the first embodiment was able to be made larger than the current flowing through the semiconductor light emitting element of the comparative example.

Carriers injected from the metal reflection layer 40 are diffused in the lateral direction. Therefore, light emission occurs also under the opening 40a where the metal reflection layer 40 is not provided. However, if the width W2 of the opening 40a is excessively widened, the proportion of area into which carriers can be injected is relatively decreased and the chip size is therefore increased. Furthermore, the proportion of light reflected by the metal reflection layer 40 is decreased.

The inventors' experiment has revealed that the width W2 of the opening 40a is preferably narrower than the width W1 of the metal reflection layer 40, and is more preferably 5 μm or less by which the lateral spread of carriers injected from the metal reflection layer 40 can be reduced.

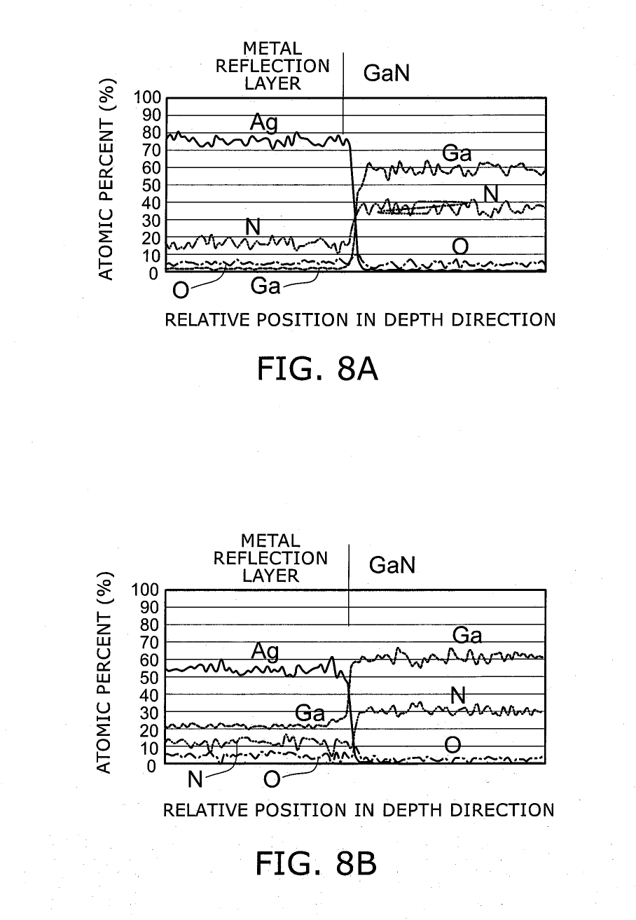

FIG. 8A is a graph showing the distribution of silver and gallium in the central portion of the metal reflection layer, and FIG. 8B is a graph showing the distribution of silver and gallium in the peripheral portion of the metal reflection layer.

The atomic percent (%) of each element was measured using an energy dispersive X-ray spectrometer (EDX) attached to a transmission electron microscope. The vertical axis is the atomic percent (%), and the horizontal axis is the relative position in the depth direction near the interface between the metal reflection layer 40 and the stacked body (GaN) 30.

In FIG. 8A, the atomic percent of silver on the second electrode 52 side is approximately between 70 and 80%, and the atomic percent of gallium (Ga) is approximately 3% or less. On the other hand, in FIG. 8B, the atomic percent of silver (Ag) is 52 to 63%, and the atomic percent of gallium is 20 to 30%. That is, the atomic percent of gallium in the peripheral portion is as high as about ten times the atomic percent in the central portion.

In the central portion of the electrode shown in FIG. 8A, the atomic percent of oxygen (O) in the metal reflection layer 40 and the stacked body 30 is substantially the same, which is near 5%. On the other hand, in the peripheral portion shown in FIG. 8B, the atomic percent of oxygen is between 5 and 10% on the metal reflection layer 40 side, but on the stacked body 30 side, in contrast, it is as low as between 0 and 3%.

That is, it has been revealed that near the opening, oxygen is incorporated in a large amount and Ga is diffused in a larger amount in a region of the metal reflection layer 40 on the side of the interface with the stacked body 30 including GaN. That is, in FIGS. 1A and 1B, it is shown that gallium can be diffused to each island-like body at an equal level. The current injected from such an island-like body of the metal reflection layer 40 into the stacked body 30 can reduce the non-uniformity of the current distribution between island-like bodies. As a result, it is considered that a near field pattern with a more uniform light intensity like FIG. 7B can be obtained.

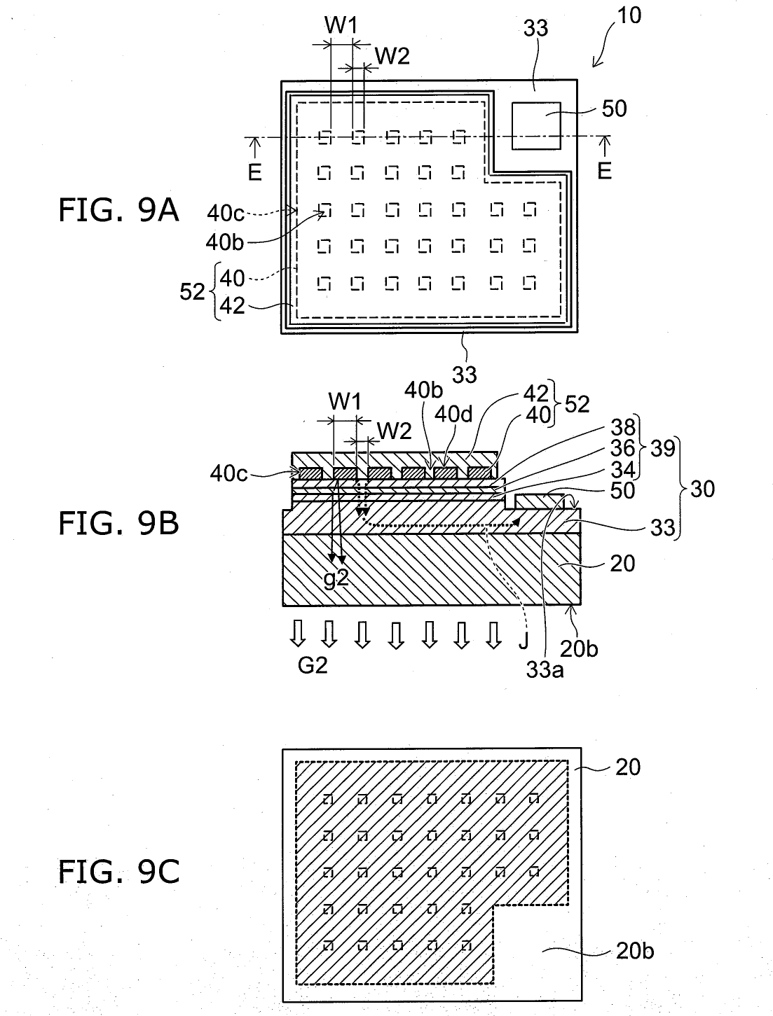

FIG. 9A is a schematic plan view of a semiconductor light emitting element according to a second embodiment, FIG. 9B is a schematic cross-sectional view taken along line E-E, and FIG. 9C is a schematic bottom view showing a light emitting region on the substrate side.

The metal reflection layer 40 has a mesh-like structure. Openings 40b are provided in the mesh-like structure. The first surface 30a of the stacked body 30 is exposed at the opening 40b. In the case where the metal reflection layer 40 is mesh-like, the metal pad portion 42 may be provided so as to fill at least part of the opening 40b.

The metal pad portion 42 may be formed of a solder layer or a metal bump, and be bonded to a lead included in a mounting member. In FIG. 9C, a light emitting region on the substrate 20 side is shown by the shaded portion. Except for a small region where the opening 40b is provided, light can be uniformly emitted from the light emitting layer 36, and light G2 can be emitted.

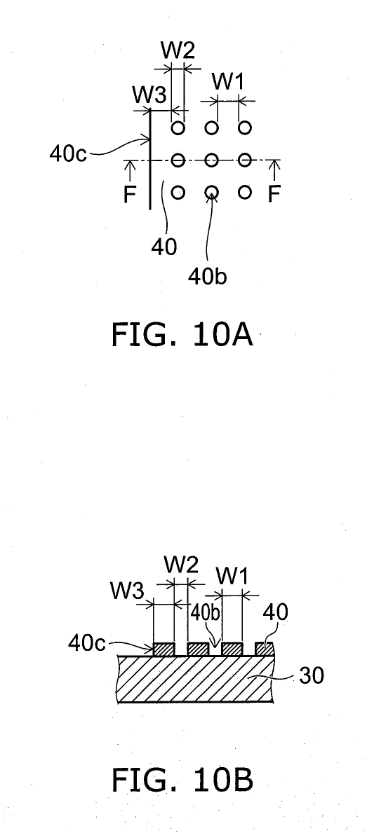

FIG. 10A is a schematic plan view of a metal reflection layer including a mesh-like structure having circular openings, and FIG. 10B is a schematic cross-sectional view taken along line F-F.

The shape of the opening 40b may be a rectangle, circle, ellipse, polygon, stripe, or the like. The width W2 of the opening 40b is defined as the longest distance in one opening 40b. The width W1 of a netlike body in the mesh-like structure is defined as the shortest distance between two openings 40b. Although there may be a difference in size between openings 40b, the openings 40b are preferably made the same shape and arranged regularly because the light intensity distribution can be made more uniform. Also when there is a difference in size between openings 40b, the minimum value of the widths W1 of the mesh-like body in the mesh-like structure is preferably set larger than the maximum value of the width W2 of the opening 40b. The area ratio of the metal reflection layer 40 to the metal pad portion 42 can be made higher when the metal reflection layer 40 is configured to have a mesh-like structure than when it is configured to have an island-like structure. Therefore, for example, it is easy to increase the light output.

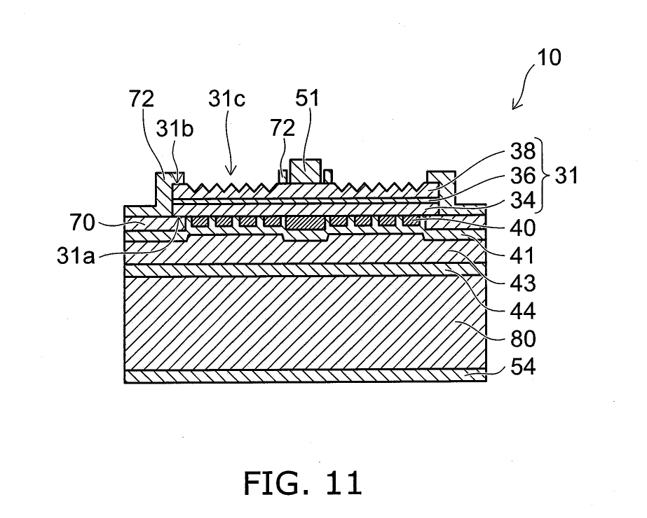

FIG. 11 is a schematic cross-sectional view of a semiconductor light emitting element according to a third embodiment.

A stacked body 31 includes the second layer 34 that is the p type, the light emitting layer 36, and the third layer 38 that is the n type. The metal reflection layer 40 is provided on the first surface 31a of the stacked body 31. The metal reflection layer 40 may be configured to have, for example, a mesh-like structure or an island-like structure. For example, in the case of an island-like structure, a metal pad portion 41 is provided so as to cover an opening provided between island-like bodies and the surface of the island-like body. The metal pad portion 41 may be, for example, Ti/Pt/Au or the like. On the other hand, a barrier metal layer 44 made of Ti/Pt/Au or the like is provided on a support substrate 80.

The substrate 80 and the stacked body 31 side are bonded by, for example, a solder layer 43 of AuSn or the like. When the support substrate 80 is made of silicon or the like, the strength of the chip can be preserved even if a substrate (sapphire etc.) for growing the stacked body 31 is removed. Thus, the thickness of the stacked body 31 can be made as thin as 10 μm or less, for example. By providing the support substrate 80 with electrical conductivity, a back surface electrode 54 can be provided on the back surface side of the support substrate 80.

In the third embodiment, a concave-convex structure 31c may be provided at a second surface of the stacked body 31; thereby, the light extraction efficiency can be further increased. In this case, a first electrode 51 may be provided on the second surface 31b of the stacked body 31. It is also possible for the second layer 34 to be the n type and for the third layer 38 to be the p type.

The first to third embodiments provide a semiconductor light emitting element in which the light intensity distribution is uniform and the light output is increased and a method for manufacturing the same. Such semiconductor light emitting elements can be widely used for illumination equipment, display devices, traffic signals, etc. Furthermore, in the manufacturing method, since the contact resistance with a nitride-based stacked body is reduced, a process for forming a transparent conductive film of ITO (indium tin oxide) or the like is not needed. Thus, it is possible to manufacture semiconductor light emitting elements with good mass productivity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting element comprising:
a stacked body made of InₓGa_{y}Al_{1-x-y}N (0≦x≦1, 0≦y≦1, x+y≦1), having a first surface and a second surface on an opposite side of the first surface and including a light emitting layer;
a metal reflection layer provided on the first surface of the stacked body, including silver or a silver alloy, and having a mesh-like structure; and
a metal pad portion provided so as to cover the first surface of the stacked body exposed at an opening provided in the mesh-like structure and a surface of the metal reflection layer,
light emitted from the light emitting layer being emitted from the second surface side of the stacked body.

2. The element according to claim 1, wherein a width of a mesh-like body in the mesh-like structure is 30 μm or less and wider than a width of the opening.

3. The element according to claim 1, wherein a shape of the opening is one of a rectangle, a circle, an ellipse, a polygon, and a stripe.

4. The element according to claim 1, further comprising:
a substrate provided on the second surface side of the stacked body and having transparency.

5. The element according to claim 4, wherein the substrate includes sapphire.

6. The element according to claim 1, wherein the metal reflection layer further includes nickel on the metal pad portion side.

7. The element according to claim 1, further comprising:
a mounting member bonded to the metal pad portion via a solder layer or a metal bump.

8. The element according to claim 1, further comprising:
a support substrate provided on the first surface side of the stacked body.

9. A semiconductor light emitting element comprising:
a stacked body made of InₓGa_{y}Al_{1-x-y}N (0≦x≦1, 0≦y≦1, x+y≦1), having a first surface and a second surface on an opposite side of the first surface and including a light emitting layer;
a metal reflection layer provided on the first surface of the stacked body, including silver or a silver alloy, and having an island-like structure; and
a metal pad portion provided so as to cover the first surface of the stacked body exposed at an opening provided in the island-like structure and a surface of the metal reflection layer,
light emitted from the light emitting layer being emitted from the second surface side of the stacked body.

10. The element according to claim 9, wherein a width of an island-like body in the island-like structure is 30 μm or less and wider than a width of the opening.

11. The element according to claim 10, wherein the width of the opening is 5 μm or less.

12. The element according to claim 9, wherein a shape of the island-like body is one of a rectangle, a circle, an ellipse, a polygon and a stripe.

13. The element according to claim 9, further comprising:
a substrate provided on the second surface side of the stacked body and having transparency.

14. The element according to claim 13, wherein the substrate includes sapphire.

15. The element according to claim 8, wherein the metal reflection layer further includes nickel on the metal pad unit side.

16. The element according to claim 9, further comprising:
a mounting member bonded to the metal pad unit via a solder layer or a metal bump.

17. The element according to claim 9, further comprising:
a support substrate provided on the first surface side of the stacked body.

18. A method for manufacturing a semiconductor light emitting element comprising:
forming a stacked body made of InₓGa_{y}Al_{1-x-y}N (0≦x≦1, 0≦y≦1, x+y≦1) including a light emitting layer on a crystal growth substrate;
forming a metal film including silver or a silver alloy on a surface of the stacked body;
forming an opening in the metal film to expose a surface of the stacked body to form a metal reflection layer having a mesh-like structure or an island-like structure and then performing heat treatment in an atmosphere containing oxygen; and
forming a metal pad portion so as to cover part of a region exposed at the opening of the surface of the stacked body and a surface of the metal reflection layer.

19. The method according to claim 18, wherein the crystal growth substrate includes sapphire.

20. The method according to claim 18, further comprising:
bonding a surface side of the metal pad portion and a substrate having electrical conductivity and removing the crystal growth substrate.
